(19) United States
(12) Patent Application Publication
(10) Pub. No.: US 2021/0028139 A1
(43) Pub. Date: Jan. 28, 2021

(54) Method for Monitoring Generation of a Nickel Metal Silicide

(71) Applicant: Shanghai Huali Integrated Circuit Corporation, Shanghai (CN)

(72) Inventors: Jiazhang Xu, Shanghai (CN); Minchun Cai, Shanghai (CN)

(73) Assignee: Shanghai Huali Integrated Circuit Corporation, Shanghai (CN)

(21) Appl. No.: 16/822,984

(22) Filed: Mar. 18, 2020

(30) Foreign Application Priority Data
Jul. 22, 2019 (CN) 2019106591027

(51) Int. Cl. H01L 23/00; H01L 21/3205; H01L 21/285

(52) U.S. Cl. CPC H01L 24/14; H01L 21/28518; H01L 21/32053

(57) ABSTRACT

Disclosed are a method for monitoring generation of a nickel metal silicide, comprising the steps: step 1, sequentially forming a first dielectric layer and a second polysilicon layer on the surface of a test silicon wafer; step 2, forming a nickel-platinum alloy on the surface of the second polysilicon layer; step 3, performing first annealing process to form a first nickel metal silicide having a molecular formula of Ni₂Si; step 4, removing the unreacted nickel-platinum alloy remaining on the surface of the nickel metal silicide; and step 5, measuring the square resistance of the first nickel metal silicide to monitor the first annealing process. The stability and reliability of the monitoring result can be improved and misjudgment can be prevented.

### CROSS REFERENCE TO RELATED APPLICATIONS

The present application claims priority to and the benefit of Chinese Patent Application No. 2019106591027 filed on Jul. 22, 2019, the disclosure of which is incorporated herein by reference in its entirety as part of the present application.

### BACKGROUND

The present invention relates to a method for manufacturing a semiconductor integrated circuit, and in particular to a method for monitoring generation of a nickel metal silicide.

In the manufacture of semiconductor integrated circuits, metal silicides are usually used to reduce the contact resistance. For example, contact holes are formed at the top of the source and drain regions of a CMOS device such as an NMOS or PMOS tube and at the top of a polysilicon gate, contacts between the source, drain, and polysilicon gates and the top contact holes usually require metal silicide. The formation of a metal silicide is usually formed by a self-alignment process, that is, the region where the metal silicide needs to be formed is first opened by using a photolithography process to expose silicon, and other places are covered with a barrier layer formed by a dielectric layer, such as a nitride layer; after that, a metal or metal alloy is formed, and then annealing is performed in a way that the formed metal or metal alloy reacts with the contacted silicon and self-aligns to form a metal silicide in a formation region of the metal silicide. With the development of technologies, the key dimensions of devices have been continuously reduced in proportion. Especially in process nodes below 65 nm, nickel metal silicides are commonly used.

In the formation of a nickel metal silicide, a nickel-platinum alloy is usually formed first, and then annealing is performed on the nickel-platinum alloy. During the annealing process, the nickel-platinum alloy in contact with silicon will form a nickel metal silicide. The annealing process is usually implemented as two-step annealing. The first annealing causes the nickel-platinum alloy to react with silicon to form Ni₂Si; the second annealing converts Ni₂Si to NiSi. If the nickel metal silicide with good Ni₂Si molecular structure cannot be formed in the first annealing, the conductivity of the nickel metal silicide will be affected. Usually, the first annealing needs to be monitored. FIG. 1A to FIG. 1C show schematic diagrams of the device structure in each step of the existing method for monitoring the generation of a nickel metal silicide; the existing method for monitoring the generation of a nickel metal silicide includes the following steps.

In step 1, as shown in FIG. 1A, a test silicon wafer 101 is provided, and a nickel-platinum alloy 102 is formed on a surface of the test silicon wafer 101.

Generally, the nickel-platinum alloy 102 is formed by a sputtering process.

After the nickel-platinum alloy 102 is formed, a step of forming a protective layer composed of TiN on the surface of the nickel-platinum alloy 102 is further included. The protective layer prevents the nickel-platinum alloy 102 from being oxidized, and the protective layer is also formed by the sputtering process.

In step 2, as shown in FIG. 1B, first annealing process for generating the first nickel metal silicide 103 is performed. The first annealing process causes the nickel-platinum alloy 102 to react with silicon to form the first nickel metal silicide 103 having a molecular formula of Ni₂Si.

Generally, the first annealing process is rapid thermal annealing (RTP). The temperature of the first annealing process ranges from 200° C. to 350° C.

In step 3, as shown in FIG. 1C, the square resistance of the first nickel metal silicide 103 is measured to monitor the first annealing process.

Generally, a four-probe tester is used to test the square resistance, and the four probes are indicated by reference numeral 104.

A multi-point test is performed on the test silicon wafer 101. Test points are uniformly distributed on the test silicon wafer 101. The data for monitoring the first annealing process includes the square resistance and the distribution uniformity of the square resistance.

When the data monitored in step 3 is out of range, the process parameters of the first annealing process in step 3 are adjusted, and then steps 1 to 3 are repeated. When the data monitored in step 3 is within a required range, the process parameters of the first annealing process are used to produce the product silicon wafer. In the production of silicon wafer products, second annealing process is also included after the first annealing process is completed. The second annealing process converts the first nickel metal silicide 103 into a second nickel metal silicide having a molecular formula of NiSi. In the existing method, when the test is performed in step 3, the test result will be affected by the resistance of the test silicon wafer 101, and the nickel-platinum alloy 102 remaining on top of the first nickel metal silicide 103 will also affect the test result. Therefore, the square resistance and uniformity of the nickel metal silicide cannot be monitored steadily, which easily leads to misjudgment.

### BRIEF SUMMARY

The technical problem to be solved by the present invention is to provide a method for monitoring generation of a nickel metal silicide, which can improve the stability and reliability of the monitoring result and prevent misjudgment.

In order to solve the above technical problem, the method for monitoring generation of a nickel metal silicide, provided by the present invention, includes the following steps:

step 1, providing a test silicon wafer, and sequentially forming a first dielectric layer and a second polysilicon layer on the surface of the test silicon wafer, wherein the first dielectric layer functions as an isolation layer between the test silicon wafer and a first nickel metal silicide formed subsequently;

step 2, forming a nickel-platinum alloy on the surface of the second polysilicon layer;

step 3, performing first annealing process to form a first nickel metal silicide, wherein the first annealing process causes the nickel-platinum alloy and the silicon of the second polysilicon layer to react to form the first nickel metal silicide having a molecular formula of Ni₂Si.

step 4, removing the unreacted nickel-platinum alloy remaining on the surface of the first nickel metal silicide; and

step 5, measuring the square resistance of the first nickel metal silicide to monitor the first annealing process.

As a further improvement, the material of the first dielectric layer includes an oxide layer or a nitride layer.

As a further improvement, the nickel-platinum alloy is formed by a sputtering process in step 2.

As a further improvement, after the nickel-platinum alloy is formed in step 2, a step of forming a third protective layer on the surface of the nickel-platinum alloy is further included, and the third protective layer prevents the nickel-platinum alloy from being oxidized; in step 4, the third protective layer needs to be removed first, and then the nickel-platinum alloy is removed.

As a further improvement, the material of the third protective layer includes TiN.

As a further improvement, the third protective layer is formed by the sputtering process.

As a further improvement, the first annealing process in step 3 is rapid thermal annealing (RTP).

As a further improvement, the temperature of the first annealing process ranges from 200° C. to 350° C.

As a further improvement, a four-probe tester is used to test the square resistance in step 4.

As a further improvement, a multi-point test is performed on the test silicon wafer in step 5.

As a further improvement, test points in step 5 are uniformly distributed on the test silicon wafer.

As a further improvement, the data for monitoring the first annealing process in step 5 includes the square resistance and the distribution uniformity of the square resistance.

As a further improvement, when the data monitored in step 5 is out of range, the process parameters of the first annealing process in step 3 are adjusted, and then steps 1 to 5 are repeated.

As a further improvement, when the data monitored in step 5 is within a required range, the process parameters of the first annealing process are used to produce the product silicon wafer.

As a further improvement, in the production process of the product silicon wafer, the following steps are included.

First, a formation region of the nickel metal silicide on the product silicon wafer is opened.

Second, a nickel-platinum alloy is formed.

Then, first annealing process is performed to form the first nickel metal silicide in the formation region of the nickel metal silicide.

And then, the unreacted nickel-platinum alloy remaining on the surface of the first nickel metal silicide is removed.

Finally, second annealing process is performed to convert the first nickel metal silicide into a second nickel metal silicide having a molecular formula of NiSi.

Compared with the method for monitoring the generation of a nickel metal silicide in the prior art where a nickel metal silicide is directly formed on a test silicon wafer and measured, the present invention is implemented in the following way: a first dielectric layer is first formed on the test silicon wafer to isolate the effect of the resistance of the test silicon wafer on the first nickel metal silicide; after that, a second polysilicon layer is formed on the first dielectric layer, and then a first nickel metal silicide is formed on the second polysilicon layer, and the unreacted nickel-platinum alloy remaining on the surface of the first nickel metal silicide is removed before the square resistance of the first nickel metal silicide is measured. In this way, the influence of the nickel-platinum alloy on the test of the first nickel metal silicide can be prevented, so the present invention simultaneously eliminates the influence of the silicon wafer itself on the square resistance test of the first nickel metal silicide and eliminates the influence of the remaining nickel-platinum alloy on the square resistance test of the first nickel metal silicide, thus improving the stability and reliability of the monitoring result, preventing misjudgment, and further improving the quality and yield of the product.

### BRIEF DESCRIPTION OF THE DRAWINGS

The present invention will be described in further detail below with reference to the accompanying drawings and specific embodiments.

FIG. 1A to FIG. 1C are schematic diagrams of the device structure in each step of the existing method for monitoring the generation of a nickel metal silicide;

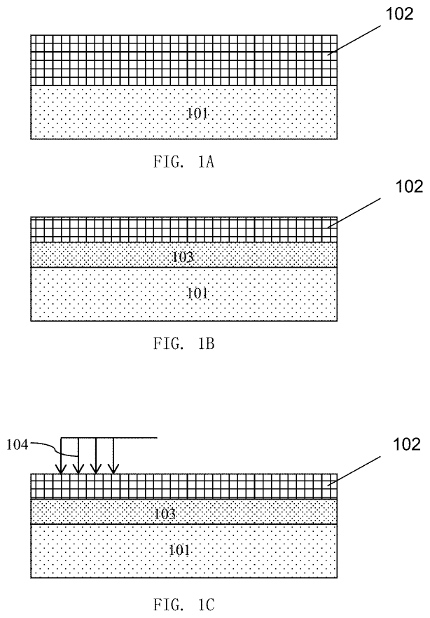

FIG. 2 is a flowchart of a method for monitoring the generation of a nickel metal silicide according to an embodiment of the present invention; and

FIG. 3A to FIG. 3E are schematic diagrams of the device structure in each step of the method for monitoring the generation of a nickel metal silicide according to an embodiment of the present invention.

### DETAILED DESCRIPTION OF THE INVENTION

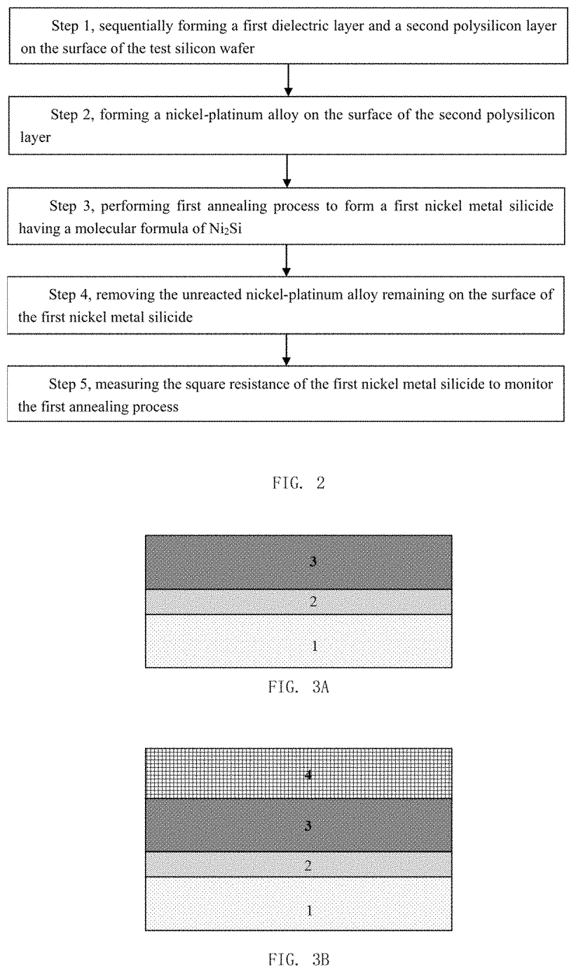

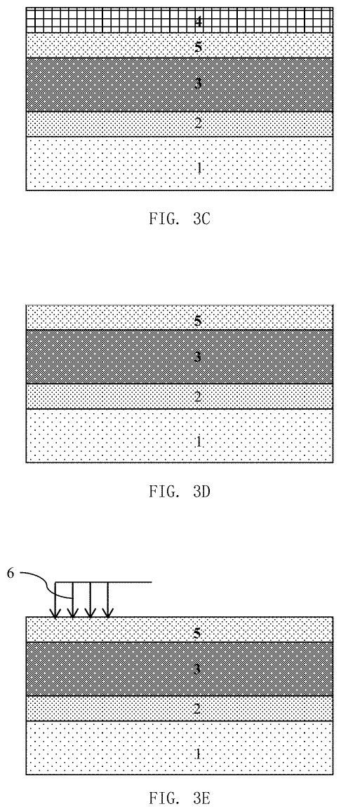

FIG. 2 shows a flowchart of a method for monitoring the generation of a nickel metal silicide according to an embodiment of the present invention; FIG. 3A to FIG. 3E show schematic diagrams of the device structure in each step of the method for monitoring the generation of a nickel metal silicide according to an embodiment of the present invention; the method for monitoring the generation of a nickel metal silicide according to an embodiment of the present invention includes the following steps.

In step 1, as shown in FIG. 3A, a test silicon wafer 1 is provided, and a first dielectric layer 2 and a second polysilicon layer 3 are sequentially formed on the surface of the test silicon wafer 1, wherein the first dielectric layer 2 functions as an isolation layer between the test silicon wafer 1 and a first nickel metal silicide 5 formed subsequently.

In the embodiments of the present invention, the material of the first dielectric layer 2 includes an oxide layer or a nitride layer.

In step 2, as shown in FIG. 3B, a nickel-platinum alloy 4 is formed on the surface of the second polysilicon layer 3.

In the embodiments of the present invention, the nickel-platinum alloy 4 is formed by a sputtering process.

Preferably, after the nickel-platinum alloy 4 is formed, a step of forming a third protective layer on the surface of the nickel-platinum alloy 4 is further included, and the third protective layer prevents the nickel-platinum alloy 4 from being oxidized; in step 4, the third protective layer needs to be removed first, and then the nickel-platinum alloy 4 is removed. Generally, the material of the third protective layer includes TiN; and the third protective layer is formed by the sputtering process.

In step 3, as shown in FIG. 3C, first annealing process for generating the first nickel metal silicide 5 is performed. The first annealing process causes the nickel-platinum alloy 4 to react with silicon of the second polysilicon layer 3 to form the first nickel metal silicide 5 having a molecular formula of Ni₂Si.

In the embodiments of the present invention, the first annealing process is rapid thermal annealing (RTP).

The temperature of the first annealing process ranges from 200° C. to 350° C.

In step 4, as shown in FIG. 3D, the unreacted nickel-platinum alloy 4 remaining on the surface of the first nickel metal silicide 5 is removed.

In step 5, as shown in FIG. 3E, the square resistance of the first nickel metal silicide 5 is measured to monitor the first annealing process.

In the embodiments of the present invention, a four-probe tester is used to test the square resistance, and the four probes are indicated by reference numeral 6.

Generally, a multi-point test is performed on the test silicon wafer 1. Test points are uniformly distributed on the test silicon wafer 1. The data for monitoring the first annealing process includes the square resistance and the distribution uniformity of the square resistance.

When the data monitored in step 5 is out of range, the process parameters of the first annealing process in step 3 are adjusted, and then steps 1 to 5 are repeated.

When the data monitored in step 5 is within a required range, the process parameters of the first annealing process are used to produce the product silicon wafer.

In the production process of the product silicon wafer, the following steps are included.

First, a formation region of the nickel metal silicide on the product silicon wafer is opened.

Second, a nickel-platinum alloy 4 is formed.

Then, the first annealing process is performed to form the first nickel metal silicide 5 in the formation region of the nickel metal silicide.

And then, the unreacted nickel-platinum alloy 4 remaining on the surface of the first nickel metal silicide is removed.

Finally, second annealing process is performed to convert the first nickel metal silicide into a second nickel metal silicide 5 having a molecular formula of NiSi. The temperature of the second annealing process is higher than the temperature of the first annealing process, so that Ni₂Si is converted into NiSi.

Compared with the method for monitoring generation of a nickel metal silicide in the prior art where a nickel metal silicide is directly formed on the test silicon wafer 1 and measured, the embodiment of the present invention is implemented in the following way: the first dielectric layer 2 is first formed on the test silicon wafer 1 to isolate the effect of the resistance of the test silicon wafer 1 on the first nickel metal silicide 5; after that, the second polysilicon layer 5 is formed on the first dielectric layer 2, and then the first nickel metal silicide is formed on the second polysilicon layer 3, and the unreacted nickel-platinum alloy 4 remaining on the surface of the first nickel metal silicide 5 is removed before the square resistance of the first nickel metal silicide 5 is measured. In this way, the influence of the nickel-platinum alloy 4 on the test of the first nickel metal silicide 5 can be prevented, so the present invention simultaneously eliminates the influence of the silicon wafer itself on the square resistance test of the first nickel metal silicide 5 and eliminates the influence of the remaining nickel-platinum alloy 4 on the square resistance test of the first nickel metal silicide 5, thus improving the stability and reliability of the monitoring result, preventing misjudgment, and further improving the quality and yield of the product.

The present invention has been described in detail through specific embodiments, but these do not constitute a limitation on the present invention. Many variations and improvements can be made by those skilled in the art without departing from the principle of the present invention, and these should also be regarded as falling within the scope of the present invention.

What is claimed is:

1. A method for monitoring generation of a nickel metal silicide, comprising the following steps:
step 1, providing a test silicon wafer, and sequentially forming a first dielectric layer and a second polysilicon layer on the surface of the test silicon wafer, wherein the first dielectric layer functions as an isolation layer between the test silicon wafer and a first nickel metal silicide formed subsequently;
step 2, forming a nickel-platinum alloy on the surface of the second polysilicon layer;
step 3, performing first annealing process to form a first nickel metal silicide, wherein the first annealing process causes the nickel-platinum alloy and the silicon of the second polysilicon layer to react to form the first nickel metal silicide having a molecular formula of Ni₂Si;
step 4, removing the unreacted nickel-platinum alloy remaining on the surface of the first nickel metal silicide; and
step 5, measuring the square resistance of the first nickel metal silicide to monitor the first annealing process.

2. The method for monitoring generation of a nickel metal silicide according to claim 1, wherein the material of the first dielectric layer comprises an oxide layer or a nitride layer.

3. The method for monitoring generation of a nickel metal silicide according to claim 1, wherein the nickel-platinum alloy is formed by a sputtering process in step 2.

4. The method for monitoring generation of a nickel metal silicide according to claim 3, wherein, after the nickel-platinum alloy is formed in step 2, a step of forming a third protective layer on the surface of the nickel-platinum alloy is further included, and the third protective layer prevents the nickel-platinum alloy from being oxidized; in step 4, the third protective layer needs to be removed first, and then the nickel-platinum alloy is removed.

5. The method for monitoring generation of a nickel metal silicide according to claim 4, wherein the material of the third protective layer comprises TiN.

6. The method for monitoring generation of a nickel metal silicide according to claim 5, wherein the third protective layer is formed by the sputtering process.

7. The method for monitoring generation of a nickel metal silicide according to claim 1, wherein the first annealing process in step 3 is rapid thermal annealing (RTP).

8. The method for monitoring generation of a nickel metal silicide according to claim 7, wherein the temperature of the first annealing process ranges from 200° C. to 350° C.

9. The method for monitoring generation of a nickel metal silicide according to claim 1, wherein a four-probe tester is used to test the square resistance in step 5.

10. The method for monitoring generation of a nickel metal silicide according to claim 9, wherein a multi-point test is performed on the test silicon wafer in step 5.

11. The method for monitoring generation of a nickel metal silicide according to claim 10, wherein test points are uniformly distributed on the test silicon wafer in step 5.

12. The method for monitoring generation of a nickel metal silicide according to claim 11, wherein the data for monitoring the first annealing process in step 5 includes the square resistance and the distribution uniformity of the square resistance.

13. The method for monitoring generation of a nickel metal silicide according to claim 12, wherein, when the data monitored in step 5 is out of range, the process parameters of the first annealing process in step 3 are adjusted, and then steps 1 to 5 are repeated.

14. The method for monitoring generation of a nickel metal silicide according to claim 12, wherein, when the data monitored in step 5 is within a required range, the process parameters of the first annealing process are used to produce the product silicon wafer.

15. The method for monitoring generation of a nickel metal silicide according to claim 14, wherein the production process of the product silicon wafer comprises:
first, opening a formation region of the nickel metal silicide on the product silicon wafer;
second, forming a nickel-platinum alloy;
then, performing first annealing process to form the first nickel metal silicide in the formation region of the nickel metal silicide;
and then, removing the unreacted nickel-platinum alloy remaining on the surface of the first nickel metal silicide; and
finally, performing second annealing process to convert the first nickel metal silicide into a second nickel metal silicide having a molecular formula of NiSi.
